(19) United States
(12) Patent Application Publication
(10) Pub. No.: US 2024/0012962 A1
(43) Pub. Date: Jan. 11, 2024

(54) DEVICE AND COMPUTER-IMPLEMENTED METHOD FOR CARRYING OUT AN EXPERIMENT USING A TECHNICAL SYSTEM OR USING A MODEL OF A TECHNICAL SYSTEM

(71) Applicant: Robert Bosch GmbH, Stuttgart (DE)

(72) Inventors: Martin Schiegg, Korntal-Muenchingen (DE); Sebastian Gerwinn, Leonberg (DE)

(21) Appl. No.: 18/341,311

(22) Filed: Jun. 26, 2023

(30) Foreign Application Priority Data
Jul. 6, 2022 (DE) 10 2022 206 889.0

(51) Int. Cl. G06F 30/20

(52) U.S. Cl. CPC G06F 30/20

(57) ABSTRACT

A device and computer-implemented method for carrying out an experiment using a technical system or using a model of a technical system. A first set of input data points for the experiment is predefined. A second set of input data points for the experiment is determined as a function of the first set of input data points. A substitute model for the technical system is configured to determine, as a function of the second set of input data points, predictions for a result of the experiment for a first prediction statistic, which is to be expected for the second set of input data points when carrying out the experiment using the technical system or using the model for the technical system.

### CROSS REFERENCE

The present application claims the benefit under 35 U.S.C. § 119 of German Patent Application No. DE 10 2022 206 889.0 filed on Jul. 6, 2022, which is expressly incorporated herein by reference in its entirety.

### FIELD

The present invention relates to a method and to a computer-implemented method for carrying out an experiment using a technical system or using a model of a technical system.

### SUMMARY

According to an example embodiment of the present invention, a computer-implemented method for carrying out an experiment using a technical system or using a model of a technical system provides that a first set of input data points for the experiment are predefined, a second set of input data points for the experiment being predetermined as a function of the first set of input data points, a substitute model for the technical system being configured to determine, as a function of the second set of input data points, predictions for a result of the experiment for a first prediction statistic, which is to be expected for the second set of input data points when carrying out the experiment using the technical system or using the model for the technical system, the second set of input data points being determined, for which an estimate of a margin between the first prediction statistic and second prediction statistic for predictions for a result of the experiment, which is to be expected for the first set of input data points when carrying out the experiment using the technical system or using the model for the technical system, is smaller than for another second set of input data points, and the experiment being carried out with the second set of input data points at the technical system or at the model for the technical system. In this way, a higher degree of accuracy is achieved when generating test cases, i.e., in the design of the experiment. Input data points from the second set of input data points are predefined for carrying out the experiment at the technical system or at the model of the technical system. The input data points define test cases, for example. With the method, a particularly good coverage is achieved, for example, using a selection of available test cases, without the available test cases collectively having to be carried out.

According to an example embodiment of the present invention, the second set of input data points is selected preferably from the first set of input data points. In this way, those input data points that are particularly suitable for the experiment, are selected from the available input data points.

According to an example embodiment of the present invention, the technical system is preferably a computer-controlled machine, in particular, a robot, preferably an at least semi-autonomous vehicle, a drive train, a manufacturing machine, a domestic appliance, a tool, an access control system or a personal assistance system. The method is particularly well suited for determining experiments, for example, for virtual or actual testing of such systems.

According to the present invention, in one example, a set of scenarios, each characterizing a road characteristic, in particular, a road curvature, a traffic characteristic, in particular, a traffic density, and/or a weather condition, is predefined by one input data point each from the first set of input data points, a set of scenarios, each characterizing a road characteristic, in particular, a road curvature, a traffic characteristic, in particular, a traffic density, and/or a weather condition, being predefined for the experiment by one input data point each from the second input data set.

According to the present invention, in one example, the technical system includes a vehicle, the result of the experiment including a distance of the vehicle from the center of a lane or to other road users, or the result including an emission or range of the vehicle.

According to an example embodiment of the present invention, it may be provided that the result of the experiment is detected and/or an instruction to activate the technical system or an instruction to change the technical system is determined and/or output as a function of the result of the experiment, and/or that the technical system is activated and/or changed as a function of the result of the experiment and/or that the substitute model is improved as a function of the result of the experiment. The detection is used, for example, for documentation and for subsequent assessment. Instructions for activating or for changing, as well as an activation or change of the system are used, for example, for changing parameters of the system or parameters, with which the system is to be operated. A further possible use is to improve the substitute model for the technical system. This substitute model is utilized, for example, for improving the technical system.

According to an example embodiment of the present invention, it may be provided that the estimate of the second prediction statistic is determined using a Gaussian process and/or that the estimate of the first prediction statistic is determined using a Gaussian process. A greater accuracy in the distributions of the simulated or measured experiments saves costs in terms of a required number of simulations, since fewer simulations or real experiments are required in order to achieve the same accuracy. A Gaussian process is defined via a mean value function and a covariance function. The Gaussian process is used here to detect uncertainties about a mapping of input data points onto output data points within the technical system. Taking this uncertainty into account improves a quality of the estimate of the prediction statistic.

The Gaussian process preferably defines a mean value function and a covariance function, the mean value function mapping the input data points onto average output data points, the covariance function mapping the input data points onto covariances between the output data points that are assigned to the input data points, the mean value function and/or the covariance function being adapted to pairs of input data points and output data points, which are observed when carrying out the experiment using the technical system or using the model for the technical system. The average output data points represent assumptions about an average profile of the mapping of the input data points onto the output data points of the technical system. A vector of input data points xₖ,k=1, . . . K is mapped, for example, onto a vector m_{GP}(x₁), . . . , m_{GP}(xₖ) of average output data points. The choice of a covariance function characterizes assumptions about a smoothness of the function, which maps input data points of the technical system onto output data points of the technical system. A vector of input data points x₁, . . . ,x_{K} is mapped, for example, onto a covariance matrix Σ, where Σ_{(i,k)}=k_{GP}(xᵢ,xₖ) is provided.

According to an example embodiment of the present invention, a computer-implemented method for determining input data points for an experiment, which is implementable using a technical system or using a model of a technical system, provides that a first set of input data points for the experiment is predefined, a second set of input data points for the experiment being determined as a function of the first set of input data points, a substitute model for the technical system being configured to determine, as a function of the second set of input data points, predictions for a result of the experiment for a first prediction statistic, which is to be expected for the second set of input data points when carrying out the experiment using the technical system or using the model for the technical system, the second set of input data points being determined, for which an estimate of a margin between the first prediction statistic and second prediction statistic for predictions for a result of the experiment, which is to be expected for the first set of input data points when carrying out the experiment using the technical system or using the model for the technical system, is smaller than for another second set of input data points.

According to an example embodiment of the present invention, a device for carrying out an experiment using a technical system or using a model of a technical system includes at least one processor and at least one memory, the memory being designed to store instructions, upon execution of which by the at least one processor the method proceeds, and that at least one processor being designed to execute the instructions. This device has advantages, which correspond to those of the method.

According to an example embodiment of the present invention, the device preferably includes an interface, which is designed to predefine input data points for carrying out an experiment at the technical system or at the model of the technical system and/or to detect a result of an experiment carried out at the technical system or at the model of the technical system, and/or to output an instruction for activating the technical system or an instruction for changing the technical system as a function of a result of an experiment carried out at the technical system or at the model of the technical system.

According to an example embodiment of the present invention, a computer program includes instructions readable by a computer, upon execution of which by the computer the method proceeds.

### BRIEF DESCRIPTION OF THE DRAWINGS

Further advantageous specific embodiments of the present invention may be derived from the following description and from the figures.

FIG. 1 schematically shows a representation of a device for carrying out an experiment, according to an example embodiment of the present invention.

FIG. 2 schematically shows a representation of an architecture for carrying out the experiment, according to an example embodiment of the present invention.

FIG. 3 shows a method for carrying out the experiment, according to an example embodiment of the present invention.

### DETAILED DESCRIPTION OF EXAMPLE EMBODIMENTS

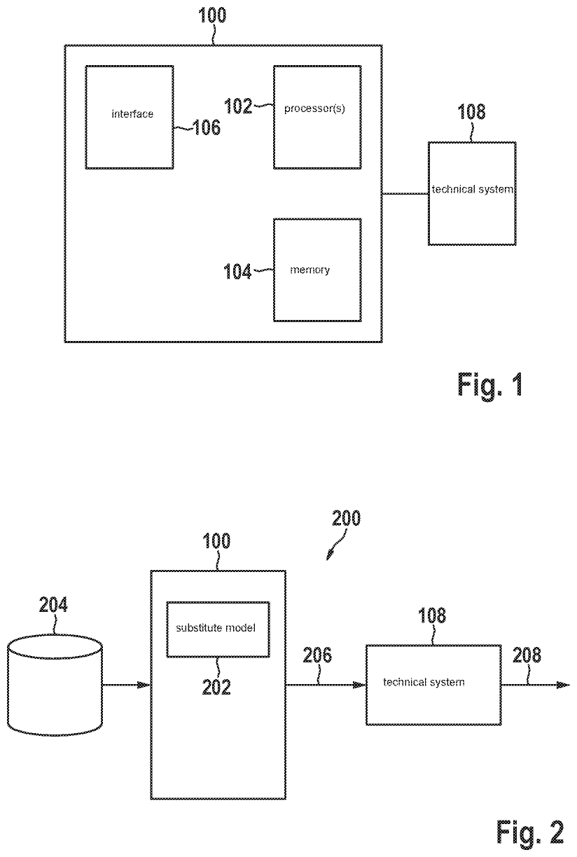

A device 100 is schematically represented in FIG. 1.

Device 100 includes at least one processor 102 and at least one memory 104. Device 100 in the example includes an interface 106.

Device 100 is designed to determine input data points for a technical system 108. Device 100 in the example is designed to determine input data points for an experiment, which is implementable using technical system 108 or using a model of technical system 108. Device 100 is designed to carry out the experiment.

In one example, technical system 108 is a computer-controlled machine.

In one example, technical system 108 is a robot. In one example, technical system 108 is an at least semi-autonomous vehicle, a drive train, a manufacturing machine, a domestic appliance, a tool, an access control system or a personal assistance system.

Memory 104 is designed to store instructions, upon execution of which by at least one processor 102 a method described below proceeds.

The at least one processor 102 is designed to execute the instructions.

Technical system 108 is designed to carry out the experiment. Instead of technical system 108, the model of the technical system 108 may be provided, which is designed to carry out the experiment.

Interface 106 in the example is designed to predefine input data points for carrying out the experiment at technical system 108 or at the model of the technical system 108.

Interface 106 in the example is designed to detect a result of an experiment carried out at technical system 108 or at the model of technical system 108.

Interface 106 in the example is designed to output an instruction for activating technical system 108 or an instruction for changing technical system 108 as a function of a result of an experiment carried out at technical system 108 or at the model of technical system 108.

An architecture 200 for carrying out the experiment is schematically represented in FIG. 2.

Architecture 200 in the example includes technical system 108. It may also be provided that architecture 200 includes the model of technical system 108.

Architecture 200 in the example includes device 100. Device 100 includes a substitute model 202 in architecture 200.

Architecture 200 in the example includes a first set of N input data points 204:

(xᵢ^{p})_{i=1, . . . ,N}

which are provided to device 100.

Device 100 provides technical system 108 a second set of M input data points 206:

(xᵢ^{q})_{i=1, . . . ,M}

Technical system 108 provides a result 208 of the experiment.

Substitute model 202 for technical system 108 is configured to determine for a data point from the second set of input data points 202 a prediction for result 208 of the experiment, which would result for this data point of the second set of input data points when carrying out the experiment using technical system 108 or using the model for technical system 108.

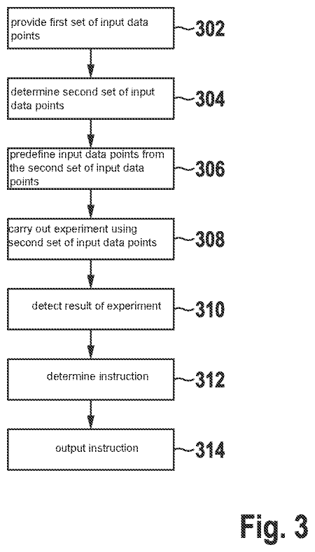

The method is schematically represented in FIG. 3.

The method includes a step 302.

In step 302, the first set of input data points (xᵢ^{p})_{i=1, . . . , N} for the experiment is provided. For example, the first set of input data points (xᵢ^{p})_{i=1, . . . ,N} includes in an open model, in which not all possible states of technical system 108 are specifiable, a number of scenarios, which are specified by one input data point each. In a closed model, in which all possible states of technical system 108 are specifiable, the first set of input data points (xᵢ^{p})_{i=1, . . . , N} includes the input data points which specify the possible scenarios.

The method includes a step 304.

In step 304, the second set of input data points (xᵢ^{p})*_{i=1, . . . , M} for the experiment is determined as a function of the first set of input data points (xᵢ^{p})_{i=1, . . . , N}.

The second set of input data points (xᵢ^{q})*_{i=1, . . . , M} in one example is determined as a function of an estimate of a margin between a first prediction statistic Y^{q}|x^{q}:=Y^{q}=(Yᵢ^{q})_{i=1, . . . , M} and a second prediction statistic Y^{p}|x^{p}:=Y^{p}=(Yᵢ^{p})_{i=1, . . . , N} This means that the prediction statistics are vectoral-valued random variables, which indicate the possible results 208 during operation of technical system 108 using the respective input data points.

The first prediction statistic Y^{q} is about the predictions of results 208, which substitute model 202 would determine for the data points from the second set of input data points (xᵢ^{q})*_{i=1, . . . , M}.

The second prediction statistic Y^{p} is about results 208, which would be obtained if the experiment were to be carried out with data points from the first set of input data points (xᵢ^{p})_{i=1, . . . , N} using technical system 108 or using the model for technical system 108.

An estimate for results of the experiments, which are not available at the real technical system before they are carried out, is carried out, for example, with the aid of substitute model 202.

The estimate in the example is a function of input data points from the first set of input data points (xᵢ^{p})_{i=1, . . . , N} and of the second set of input data points (xᵢ^{q})*_{i=1, . . . , M}.

In the example, the second set of input data points (xᵢ^{q})*_{i=1, . . . , M} is determined, for which the estimate of the margin between the prediction statistic Y^{q} and the prediction statistic Yₚ is smaller than for another second set of input data points.

The second set of input data points (xᵢ^{q})*_{i=1, . . . ,M} in the example is selected from the first set of input data points (xᵢ^{p})_{i=1, . . . ,N}.

The estimate in one example is determined as a function of a prediction of second prediction statistic Y^{p} using a Gaussian process GP.

The estimate in one example is determined as a function of a prediction of first prediction statistic Y^{q} using a Gaussian process GP.

The prediction includes, for example, a mean value function and a covariance function.

Gaussian process GP may be pre-trained or is used with no previous training.

For a mean value μ and a covariance matrix Σ, Gaussian process GP includes the Gaussian density function

$$Φ ( y , μ , \sum ) = exp ( - \frac{1}{2} {( y - μ )}^{T} {\sum }^{- 1} ( y - μ ) ) \frac{1}{\sqrt{{( 2 π )}^{2} \vert \sum \vert}}$$

A training of Gaussian process GP is described below. During training, a mean value function m_{GP} and a covariance function k_{GP} of Gaussian process GP are determined. In the example, the mean value function m_{GP} and covariance function k_{GP} of Gaussian process GP are determined as a function of observations (X^{GP},Y^{GP}). Observations (X^{GP},Y^{GP}) include pairs of input data points and output data points. In the example, the mean value function m GP and covariance function k_{GP} are predefined and are adapted as a function of observations (X^{GP},Y^{GP}). The mean value function changed as a result this adaptation is

μ(x)=m_{gp}(x)+k_{gp}(x,X^{GP})k_{gp}(X^{GP},X^{GP})⁻¹(Y^{GP}−m^{GP}(X^{GP}))

The covariance function changed as a result this adaptation is

k(x,x′)=k_{gp}(x,x′)−k_{gp}(x,X^{GP})k_{gp}(X^{GP},X^{GP})⁻¹k_{gp}(X^{GP},x′)

where m_{gp}(x) is a function, which describes the average behavior of technical system 108, and which maps the one data point x onto a value of result 208. m_{gp}(x) may also be the function for simulating the technical system.

In one example, a set of input data points X^{GP} and associated output data points Y^{GP} are provided for the method, output data points Y^{GP} being detected for the set of input data points X^{GP} when carrying out the experiment using technical system 108 or using the model for technical system 108.

m_{GP}(X^{GP}) represents a mean value of the set of input data points X^{GP}.

Mean value μ(x) for a data point x is defined as a function of the value of function m_{gp}(x) for this data point x. Mean value μ(x) is defined as a function of a deviation (Y^{GP}−m_{GP}(X^{GP})) of mean value m_{GP}(X^{GP}) from observed output data points Y^{GP}.

In one example, X^{GP}={ } is initialized.

In one example, Y^{GP}={ } is initialized.

Covariance function k(x,x′) is defined as a function of a covariance of first data point x and of a second data point x′.

Covariance function k(x,x′) is defined as a function of the covariance function of Gaussian process k_{GP}, of its evaluation on the set of input data points k_{GP}(X^{GP},X^{GP}) as well as of covariance k_{GP}(X^{GP},x′) between the set of input data X^{GP} and a second data point x′.

The formulas for μ(x) and k(x,x′) include adaptation formulas for a Gaussian process including mean value function m_{gp}(x) and covariance function k_{gp}. The estimate of the deviations of the prediction statistics is determined in one example as follows:

J(x^{q})=E_{Y}_{^{p}}_{,Y}_{^{q}}[MMD[Y^{p},Y^{q};k_{y}]]+γ\sqrt{V[MMD[Y^{p},Y^{q};k_{y}]]}

with a maximum average deviation

$$MMD [ {Y}^{p} , {Y}^{q} ; {k}_{y} ] = \frac{1}{{N}^{2}} {\sum }_{i , j} {k}_{y} ( {Y}_{i}^{p} , {Y}_{j}^{p} ) - \frac{2}{MN} {\sum }_{i , j} {k}_{y} ( {Y}_{i}^{p} , {Y}_{j}^{p} ) + \frac{1}{{M}^{2}} {\sum }_{i , j} {k}_{y} ( {Y}_{i}^{p} , {Y}_{j}^{p} )$$

In one example, the core

$${k}_{gp} = exp ( - \frac{{‖ x - {x}^{′} ‖}^{2}}{2 {λ}_{x}} )$$

of the Gaussian process and the core of

$${k}_{y} = exp ( - \frac{{‖ y - {y}^{′} ‖}^{2}}{2 {λ}_{y}} )$$

the maximum average deviation MMD are squared exponential cores. It is then possible to calculate the estimate J(x^{q}) in closed form.

The estimate J(x^{q}) is a target of an optimization.

$${( {x}^{q} )}^{*} = arg {min}_{{x}^{q}} J ( {x}^{q} )$$

The optimization is carried out using k(x,x)=k(x) and [N]={1, . . . ,N} and [M]={1, . . . ,M} in closed form using the following expected value.

$${E}_{{Y}^{p} , {Y}^{q}} [ MMD [ {Y}^{p} , {Y}^{q} ; {k}_{y} ] ] = \frac{\sqrt{2 π {λ}_{y}}}{{N}^{2}} {\sum }_{i ∈ [ N ]} {\sum }_{j ∈ [ N ]} Φ ( μ ( {x}_{i}^{p} ) , μ ( {x}_{j}^{p} ) , {λ}_{y} + k ( {x}_{i}^{p} ) + k ( {x}_{j}^{p} ) - 2 k ( {x}_{i}^{p} , {x}_{j}^{p} ) ) - \frac{\sqrt{2 π {λ}_{y}}}{NM} {\sum }_{i ∈ [ N ]} {\sum }_{j ∈ [ M ]} Φ ( μ ( {x}_{i}^{p} ) , μ ( {x}_{j}^{q} ) , {λ}_{y} + k ( {x}_{i}^{p} ) + k ( {x}_{j}^{q} ) - 2 k ( {x}_{i}^{p} , {x}_{j}^{q} ) ) + \frac{\sqrt{2 π {λ}_{y}}}{{M}^{2}} {\sum }_{i ∈ [ M ]} {\sum }_{j ∈ [ M ]} Φ ( μ ( {x}_{i}^{q} ) , μ ( {x}_{j}^{q} ) , {λ}_{y} + k ( {x}_{i}^{q} ) + k ( {x}_{j}^{q} ) - 2 k ( {x}_{i}^{q} , {x}_{j}^{q} ) )$$

and the following variance:

V[MMD[Y^{p},Y^{q};k_{y}]]=E_{Y}_{^{p}}_{,Y}_{^{q}}[MMD[Y^{p},Y^{q};k_{y}]²]−(E_{Y}_{^{p}}_{,Y}_{^{q}}[MMD[Y^{p},Y^{q};k_{y}]])²

where

$${E}_{{Y}^{p} , {Y}^{q}} [ MMD [ {Y}^{p} , {Y}^{q} ; {k}_{y} ] ] = \frac{2 π {λ}_{y}}{{N}^{4}} {\sum }_{i ∈ [ N ]} {\sum }_{j ∈ [ N ]} {\sum }_{k ∈ [ N ]} {\sum }_{l ∈ [ N ]} Ψ ( {x}_{i}^{p} , {x}_{j}^{p} , {x}_{k}^{p} , {x}_{l}^{p} , {λ}_{y} ) + \frac{8 {πλ}_{y}}{{M}^{2} {N}^{2}} {\sum }_{i ∈ [ N ]} {\sum }_{j ∈ [ M ]} {\sum }_{k ∈ [ N ]} {\sum }_{l ∈ [ M ]} Ψ ( {x}_{i}^{p} , {x}_{j}^{p} , {x}_{k}^{p} , {x}_{l}^{p} , {λ}_{y} ) + \frac{2 {πλ}_{y}}{{M}^{4}} {\sum }_{i ∈ [ M ]} {\sum }_{j ∈ [ M ]} {\sum }_{k ∈ [ M ]} {\sum }_{l ∈ [ M ]} Ψ ( {x}_{i}^{p} , {x}_{j}^{p} , {x}_{k}^{p} , {x}_{l}^{p} , {λ}_{y} ) - \frac{8 {πλ}_{y}}{{N}^{3} M} {\sum }_{i ∈ [ N ]} {\sum }_{j ∈ [ N ]} {\sum }_{k ∈ [ N ]} {\sum }_{l ∈ [ M ]} Ψ ( {x}_{i}^{p} , {x}_{j}^{p} , {x}_{k}^{p} , {x}_{l}^{p} , {λ}_{y} ) - \frac{8 {πλ}_{y}}{{M}^{3} N} {\sum }_{i ∈ [ N ]} {\sum }_{j ∈ [ N ]} {\sum }_{k ∈ [ M ]} {\sum }_{l ∈ [ M ]} Ψ ( {x}_{i}^{p} , {x}_{j}^{p} , {x}_{k}^{p} , {x}_{l}^{p} , {λ}_{y} ) - \frac{4 {πλ}_{y}}{{M}^{2} {N}^{2}} {\sum }_{i ∈ [ N ]} {\sum }_{j ∈ [ N ]} {\sum }_{k ∈ [ M ]} {\sum }_{l ∈ [ M ]} Ψ ( {x}_{i}^{p} , {x}_{j}^{p} , {x}_{k}^{p} , {x}_{l}^{p} , {λ}_{y} )$$

where

$$Ψ ( {x}_{i}^{p} , {x}_{j}^{p} , {x}_{k}^{p} , {x}_{l}^{p} , {λ}_{y} ) = Φ ( μ ( {x}_{i} , {x}_{k} ) , μ ( {x}_{j} , {x}_{l} ) , {λ}_{y} 1 + k ( ( \begin{matrix}{x}_{i} \\ {x}_{k}\end{matrix} ) , ( \begin{matrix}{x}_{i} \\ {x}_{k}\end{matrix} ) ) + k ( ( \begin{matrix}{x}_{j} \\ {x}_{l}\end{matrix} ) ( \begin{matrix}{x}_{j} \\ {x}_{l}\end{matrix} ) ) - k ( ( \begin{matrix}{x}_{i} \\ {x}_{k}\end{matrix} ) , ( \begin{matrix}{x}_{j} \\ {x}_{l}\end{matrix} ) ) - k ( ( \begin{matrix}{x}_{j} \\ {x}_{l}\end{matrix} ) , ( \begin{matrix}{x}_{i} \\ {x}_{k}\end{matrix} ) ) )$$

In one embodiment, the second set of input data points (x^{q})*₀={ } is initialized and the estimate J(xᵢ) is subsequently calculated for i=1, . . . ,M input data points xᵢ∈x^{p}, either by calculating the closed form E_{Y}_{^{p}}_{,Y}_{^{q}}[MMD[Y^{p},Y^{q};k_{y}]] and V[MMD[Y^{p}, Y^{q}; k_{y}]] or by empirical estimate. The empirical estimate offers advantages in the case of N>1000 or M>1000 with respect to the processor memory and the run-time.

For the empirical estimate, a number R of random output data points (Ŷ^{p})ⁱ,(Ŷ^{q})ⁱ,i=1, . . . R for provided input data points x^{p},x^{q} are drawn from the Gaussian process and the MMD for these input data points is then determined:

$${( {\hat{Y}}^{p} )}^{i} , {( {\hat{Y}}^{q} )}^{i} \vert {x}^{p} , {x}^{q} ∼ GP ( μ ( ( \begin{matrix}{x}^{p} \\ {x}^{q}\end{matrix} ) ) , k ( ( \begin{matrix}{x}^{p} \\ {x}^{q}\end{matrix} ) ) , ( \begin{matrix}{x}^{p} \\ {x}^{q}\end{matrix} ) ) , for i ∈ [ R ]$$

$${\hat{Z}}^{i} = MDD [ {( {\hat{Y}}^{p} )}^{i} , {( {\hat{Y}}^{q} )}^{i} , {k}_{y} ] , for i ∈ [ R ]$$

$${Ê}_{{Y}^{p} , {Y}^{q}} [ MMD [ {Y}^{p} , {Y}^{q} ; {k}_{y} ] ] = \frac{1}{R} {\sum }_{i = 1}^{R} {\hat{Z}}^{i}$$

$$\hat{V} [ MMD [ {Y}^{p} , {Y}^{q} ; {k}_{y} ] ] = \frac{1}{R - 1} {\sum }_{i = 1}^{R} {( {\hat{Z}}^{i} - {Ê}_{{Y}^{p} , {Y}^{q}} [ MDD [ {Y}^{p} , {Y}^{q} ; {k}_{y} ] ] )}^{2}$$

In the method, a solution \tilde{x}ᵢ of the optimization J((\tilde{x}₁, . . . ,\tilde{x}ᵢ₋₁,\tilde{x}ᵢ)) is determined in each case.

The second set of input data points (x^{q})*_{i=1, . . . ,M} in the example includes input data points \tilde{x}ᵢ, which are the solution of the optimization:

(x^{q})*_{i=1, . . . ,M}=\tilde{x}_{i=1, . . . ,M}

For the closed form, it may be provided to carry out the optimization using a gradient-based optimization method, for example, a gradient descent method, which determines the second set of input data points (x^{q})*_{i=1, . . . ,M}.

The method in the example provides a step 306.

Step 306 in one example includes the input data points from the second set of input data points (x^{p})_{i=1, . . . ,N} being predefined for carrying out the experiment at technical system 108 or at the model of technical system 108.

The method in the example provides a step 308.

Step 308 in one example includes the experiment being carried out using the second set of input data points (x^{p})_{i=1, . . . ,N} at technical system 108 or at the model for technical system 108.

The method in the example provides an optional step 310.

Step 310 in one example includes result 208 of the experiment being detected.

The method in the example includes an optional step 312.

Step 312 in one example includes determining an instruction for activating technical system 108 or an instruction for changing technical system 108 as a function of result 208 of the experiment.

The method in the example provides an optional step 314.

Step 314 includes outputting the instruction for activating technical system 108 or the instruction to change.

It may be provided that technical system 108 is activated or changed as a function of result 208 of the experiment.

In one exemplary embodiment for an automated vehicle or for a drive train, the method generates various scenarios, for example, by input data points, which predefine the road characteristics such as road curvature, traffic characteristics such as traffic density, or weather conditions.

Desirable scenarios for the automated vehicle generate results that include a distance of the vehicle from the center of a lane or to other road users.

Desirable scenarios for the drive train generate results that include an emission or range of the vehicle.

The desirable scenarios may be determined by simulation of the vehicle or by measurements at the vehicle during its travel.

In this way, the vehicle behavior or the behavior of the drive train may be checked, for example, for release.

For the vehicle behavior, it is checked, for example, whether the distance of the vehicle from the center of the lane or to other road users is greater than a threshold value, in particular, a safety distance.

For the behavior of the drive train, for example, it is checked whether an emission is lower than a threshold value, in particular, is an allowed emission or whether a range is greater than a threshold value, in particular, a minimum range.

It may be provided to check results, whether or not a sufficient number of results are present for release. The method is continued, for example, using new measurements, if sufficient results are not yet. It may be provided to check regardless of the result whether or not the release may be granted. If the release may be granted, the method is ended, for example. Otherwise, the method is repeated, preferably after changes have been carried out on the vehicle.

The method provides, for example, that an operating point of technical system 108, for example, of the vehicle or of the drive train is determined. Technical system 108 is operated in the operating point and the result, for example, the distance or the emission or the range, is determined. The result is used for a determination of the next input data points.

It may be provided to determine hyper-parameters or parameters of the Gaussian process, for example, of core k_{gp} of the Gaussian process and of core k_{y} of maximum average deviation MMD as a function of input data points Y^{GP} and of prediction statistic Y^{GP} or to determine these in advance using a training method.

What is claimed is:

1. A computer-implemented method for carrying out an experiment using a technical system or using a model of the technical system, the method comprising the following steps:
predefining a first set of input data points for the experiment;
determining a second set of input data points for the experiment as a function of the first set of input data points, a substitute model for the technical system being configured to determine as a function of the second set of input data points predictions for a result of the experiment for a first prediction statistic, which is to be expected for the second set of input data points when carrying out the experiment using the technical system or using the model of the technical system, the second set of input data points being determined, for which an estimate of a margin between the first prediction statistic and a second prediction statistic for predictions for a result of the experiment, which is to be expected for the first set of input data points when carrying out the experiment using the technical system or using the model for the technical system, is smaller than for another second set of input data points; and
carrying out the experiment using the second set of input data points at the technical system or at the model of the technical system.

2. The method as recited in claim 1, wherein the second set of input data points is selected from the first set of input data points.

3. The method as recited in claim 1, wherein the technical system is a computer-controlled machine, the computer-controlled machine being a robot or an at least semi-autonomous vehicle or a drive train or a manufacturing machine or a domestic appliance or a tool or an access control system or a personal assistance system.

4. The method as recited in claim 1, wherein a set of scenarios, which characterize in each case a road characteristic including a road curvature, and/or a traffic characteristic including a traffic density, and/or a weather condition, is predefined by one input data point each from the first set of input data points, a set of scenarios, which characterizes in each case a road characteristic including a road curvature, and/or a traffic characteristic including a traffic density, and/or a weather condition, being predefined by one input data point each from the second set of input data points for the experiment.

5. The method as recited in claim 1, wherein the technical system includes a vehicle, a result of the experiment including a distance of the vehicle from a center of a lane or to other road users, or the result includes an emission or the vehicle or range of the vehicle.

6. The method as recited in claim 1, wherein: i) a result of the experiment is detected, and/or ii) an instruction for activating the technical system or an instruction for changing the technical system is determined and/or output as a function of the result of the experiment, and/or iii) the technical system is activated or changed as a function of the result of the experiment, and/or iv) the substitute model is improved as a function of the result of the experiment.

7. The method as recited in claim 1, wherein an estimate of the second prediction statistic is determined using a Gaussian process and/or an estimate of the first prediction statistic is determined using a Gaussian process.

8. The method as recited in claim 7, wherein the Gaussian process defines a mean value function and a covariance function, the mean value function mapping input data points onto average output data points, the covariance function mapping the input data points onto covariances between the output data points, which are assigned to the input data points, the mean value function and/or the covariance function being adapted to pairs of input data points and output data points, which are observed when carrying out the experiment using the technical system or using the model for the technical system.

9. A computer-implemented method for determining input data points for an experiment, which is implementable using a technical system or using a model of the technical system, the method comprising the following steps:
predefining a first set of input data points for the experiment is predefined;
determining a second set of input data points for the experiment as a function of the first set of input data points, a substitute model for the technical system being configured to determine, as a function of the second set of input data points, predictions for a result of the experiment for a first prediction statistic, which is to be expected for the second set of input data points when carrying out the experiment using the technical system or using the model for the technical system, the second set of input data points being determined, for which an estimate of a margin between the first prediction statistic and a second prediction statistic for predictions for a result of the experiment, which is to be expected for the first set of input data points when carrying out the experiment using the technical system or using the model for the technical system, is smaller than for another second set of input data points.

10. A device configured to carrying out an experiment using a technical system or using a model of a technical system, the device comprising:
at least one processor; and
at least one memory, the memory being configured to store instructions, upon the execution of which by the at least one processor, the at least one processor performs the following steps:
predefining a first set of input data points for the experiment,
determining a second set of input data points for the experiment as a function of the first set of input data points, a substitute model for the technical system being configured to determine as a function of the second set of input data points predictions for a result of the experiment for a first prediction statistic, which is to be expected for the second set of input data points when carrying out the experiment using the technical system or using the model of the technical system, the second set of input data points being determined, for which an estimate of a margin between the first prediction statistic and a second prediction statistic for predictions for a result of the experiment, which is to be expected for the first set of input data points when carrying out the experiment using the technical system or using the model for the technical system, is smaller than for another second set of input data points, and
carrying out the experiment using the second set of input data points at the technical system or at the model of the technical system.

11. The device as recited in claim 10, further comprising:
an interface configured: i) to predefine input data points for carrying out an experiment at the technical system or at the model of the technical system, and/or ii) to detect a result of the experiment carried out at the technical system or at the model of the technical system, and/or iii) to output an instruction for activating the technical system or an instruction for changing the technical system as a function of a result of the experiment carried out at the technical system or at the model of the technical system.

12. A non-transitory computer-readable medium on which is stored a computer program including instructions for carrying out an experiment using a technical system or using a model of the technical system, the instruction, when executed by a computer, causing the computer to perform the following steps:
predefining a first set of input data points for the experiment;
determining a second set of input data points for the experiment as a function of the first set of input data points, a substitute model for the technical system being configured to determine as a function of the second set of input data points predictions for a result of the experiment for a first prediction statistic, which is to be expected for the second set of input data points when carrying out the experiment using the technical system or using the model of the technical system, the second set of input data points being determined, for which an estimate of a margin between the first prediction statistic and a second prediction statistic for predictions for a result of the experiment, which is to be expected for the first set of input data points when carrying out the experiment using the technical system or using the model for the technical system, is smaller than for another second set of input data points; and
carrying out the experiment using the second set of input data points at the technical system or at the model of the technical system.
